(19) United States
(12) Patent Application Publication
(10) Pub. No.: US 2002/0102812 A1
(43) Pub. Date: Aug. 1, 2002

(54) Method for improving alignment precision in forming color filter array

(76) Inventors: Jeenh-Bang Yeh, Tainan City (TW); Cheng-Der Chen, Hsin-Chu City (TW); Shih-Yao Lin, Hsin-Chu (TW)

Correspondence Address: Powell, Goldstein, Frazer & Murphy, LLP, 1001 Pennsylvania Avenue, Suite 600, Washington, DC, 20004, US

(21) Appl. No.: 09/774,463

(22) Filed: Jan. 31, 2001

(51) Int. Cl. H01L 21/76; H01L 21/302; H01L 21/461

(52) U.S. Cl. 438/401; 438/748

(57) ABSTRACT

A method for improving alignment precision in forming a color filter array is disclosed. This method comprises providing a substrate having a node region in the substrate and a dielectric layer on the substrate, and etching a portion of the dielectric layer to expose the node region. As a result, the alignment precision is improved by use of the node region with enhanced step height to increase the intensity of signal in a semiconductor process.

### BACKGROUND OF THE INVENTION

1. Field of the Invention

The present invention generally relates to a method for improving alignment precision in semiconductor processes, and more particularly to a method for improving alignment precision in forming a color filter array.

2. Description of the Prior Art

As the integration of semiconductor device increases, the photolithography process used to replicate the required pattern into the surface of the wafer is becoming more and more important. Since sequential photolithography processes are required in the wafer fabrication, it is necessary that successive photomask pattern applications be accurately aligned to the previous patterns already laid down on the integrated circuit substrate. For the purpose of such alignments of the patterns, a series of alignment marks are provided in each photomask to allow successive photomask patterns to be conveniently and accurately aligned to already-formed circuit patterns present.

There are several alignment sensors used for measuring the position of a wafer alignment mark. In the alignment system of LSA (Laser-Step-Alignment) type, a laser beam is directed onto a wafer alignment mark, and the light diffracted and scattered from the alignment mark is received by the alignment sensor to determine the position of the wafer. Then, it is used to determine whether the mask is aligned with the wafer. That is to say, alignment marks having a step height relative to the region of the wafer surrounding the alignment mark are particularly useful for automatic alignment of masks. Another type of the alignment system is FIA (Field-Image-Alignment) system. This alignment sensor in which an enlarged image of a wafer alignment mark obtained by directing light having a wide wavelength band, which is emitted from a light source, onto the alignment mark is picked up by an image element. Then, an obtained image signal is image-treated to determine whether the mask is aligned with the wafer.

However, when a color filter array is formed, in consideration of the fact that photoresist having low permeability to red/near-infrared wavelength may be used, it is required that a position of an alignment mark can be detected through a film having low permeability to red/near-infrared wavelength (about 365 nm). That is to say, in the formation of the color filter array, red, green or blue photoresist (referred to as “color photoresist” hereafter) materials is often used as the photoresist. In the case where such a color photoresist layer is used, when superimposing exposure is effected, the positions of the alignment marks provided under the color photoresist layer must be detected. However, when the red/near-infrared light is used as the illumination light from the alignment system, since the red/near-infrared light is absorbed if a green or blue photoresist is used, there arises a problem in which the green or blue photoresist having low permeability to the red/near-infrared light will lead to a miss-alignment. Even if creating another alignment mark, for the purpose of aligning successive color photoresist layers based on the alignment mark created, during the formation of the red layer of a color filter array, will not successfully solve the problem. Because the alignment mark pixel is about 4 micrometer (μm), for the present color photoresist, it has an adhesive problem, resulting in the peeling of the alignment mark.

Moreover, in the past, since no planarization step was executed in a back-end process, the alignment marks would not be harmed or removed. However, after the planarization step, such as chemical mechanical polishing processes, were introduced into the semiconductor fabrication process, the step height and the configuration specificity of the alignment marks become indistinct. Therefore, the insufficient step height of the alignment mark pattern causes the alignment sensor to reproduce a signal that is too weak and results in alignment error. Additionally, the reflectance and the refraction of each layer in the multilayer structure are different because the materials of each layer in the multilayer are different. Any deposition of a layer or layers of opaque material, such as the deposition of a layer of metal for the formation of interconnection, can obscure the alignment marks and render them useless. Hence, the alignment signal is weak or the noise ratio is large. Therefore, to insure the alignment precision in forming a color filter array is more difficult because the area of miss-alignment must be reduced with pixel size to maintain adequate color resolution.

Referring to FIG. 1 which is plotted for the purpose of graphic explanation, not for the purpose of expressing actual device, wherein a cross-sectional view of a conventional alignment mark after the planarization process executed, is shown. A substrate 110 having a node region 112 in the substrate 110 and a dielectric layer 114 on the substrate 110 is provided. The substrate 110 further comprises a device region 116. The node region 112 is defined as a conductive layer in the device region 116 and an alignment mark used in a previous process in the substrate 110. The node region 112 can be a metal layer. The alignment mark 112 can be in the scribe line of a wafer. The dielectric layer 118 can be a silicon oxide layer, a silicon oxynitride layer or a combination both layers. The step height of the alignment mark 112 is indistinct after the planarization process executed, resulting in the alignment difficulty of producing a color filter array 118 on the dielectric layer 114 in the device region 116. The color filter array 118 includes red 120, green 122, and blue 124 photoresist layers. Three dot lines, 126, 128 and 130, represent the alignment processes of forming different layers of the color filter array 118, respectively. The dot line 126 shows an accurate alignment occurred when forming the red 120 layer of the color filter array 118, but dot lines 128 and 130, respectively, shows a slight miss-alignment occurred when forming the green 122 or blue 124 layer of the color filter array 118.

### SUMMARY OF THE INVENTION

In accordance with the present invention, a method is provided for improving alignment precision in forming a color filter array. The method substantially prevents an alignment error being occurred due to the indistinct step height, which is a result of planarization processes, and improves the alignment precision in photolithography processes, especially in a forming color filter array. This method comprises providing a substrate having a node region in the substrate and a dielectric layer on the substrate, and etching a portion of the dielectric layer to expose the node region. As a result, the alignment precision is improved by use of the node region with enhanced step height to increase the intensity of signal in a semiconductor process.

It is another object of this invention that an alignment mark with enhanced step height is regenerated.

It is a further object of this invention that an alignment mark with enhanced step height is applied to the photolithography step, wherein a color filter array is formed by using the color phtoresist with low permeability to the exposure light.

It is another further object of this invention that a method for improving alignment precision by use of an alignment mark with enhanced step height in an alignment process is provided.

In one embodiment, a method for improving alignment precision in forming a color filter array is disclosed. The method comprises providing a substrate having a node region in the substrate and a dielectric layer on the substrate. The substrate further comprises a device region. The node region is defined as a conductive layer in the device region and an alignment mark used in a previous process. Then, a portion of the dielectric layer is etched to expose the node layer by use of a patterned photoresist as a mask. The steps of the etching process includes to form a photoresist on the dielectric layer, to pattern a desired shape on the photoresist, and to etch a portion of the dielectric layer by using the patterned photoresist as a mask. The patterned photoresist defines an opening overlying the alignment mark, and it can define a desired opening in the device region in situ, if the desired opening is needed. Then, the patterned photoresist is removed. Hence, the alignment mark with enhanced step height due to the concave surface is formed. Then, the substrate is aligned in successive steps by using the alignment mark with enhanced step height, and more particularly in the steps of forming a color filter array. That is to say, the alignment precision is improved by use of the alignment mark with enhanced step height to increase the intensity of signal in semiconductor processes.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic representation of structure during the alignment processes of forming a color filter array using conventional, prior art techniques;

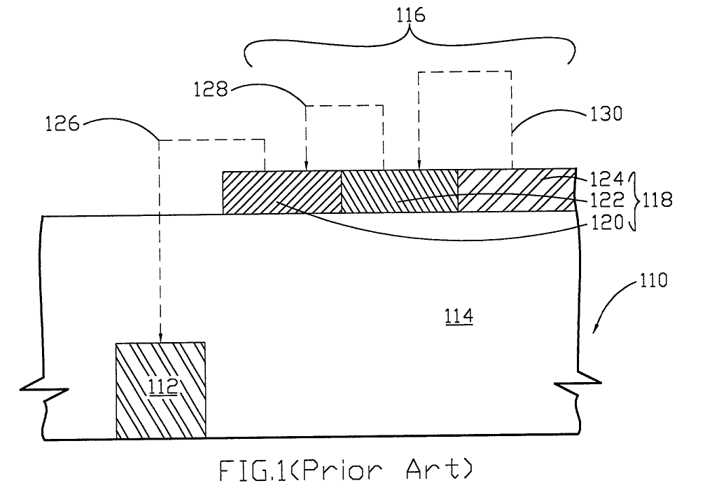

FIG. 2A to 2B are schematic representations of structures at various stages during the regeneration of the alignment mark with enhanced step height in accordance with a method disclosed; and

FIG. 3 is a schematic representation of structure during the alignment processes of forming a color filter array using the present invention.

### DESCRIPTION OF THE PREFERRED EMBODIMENT

Some sample embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

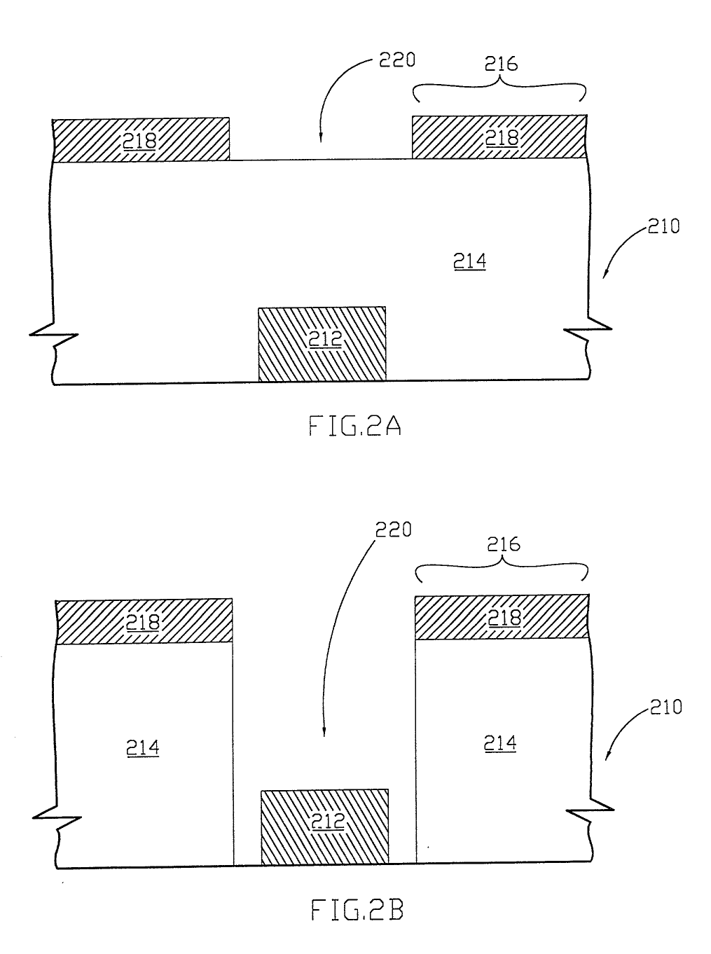

In a preferred embodiment, a method for improving alignment precision in forming a color filter array is disclosed. As shown in FIG. 2A, a substrate 210 having a node region 212 in the substrate 210 and a dielectric layer 214 on the substrate 210 is provided. The substrate 210 further comprises a device region 216. The node region 212 is defined as a conductive layer in the device region 216 and an alignment mark in the substrate 210 used in a previous process. The node region 212 can be a metal layer. The alignment mark 212 can be in the scribe line of a wafer. The dielectric layer 218 can be a silicon oxide layer, a silicon oxynitride layer or a combination both layers. Then, a patterned photoresist 218 is formed on the dielectric layer 214, wherein the patterned photoresist 218 defines an opening 220 overlying the alignment mark 212, and the patterned photoresist 218 can define a desired opening in the device region in situ, if the desired opening, such as a bonding opening, is needed.

Referring to FIG. 2B, a portion of the dielectric layer is etched to expose the node layer 212 by use of the patterned photoresist as a mask, and then, the patterned photoresist is removed. Hence, the alignment mark 212 with enhanced step height due to the concave surface is formed, and the desired opening is also formed, if the patterned photoresist defines the desired opening in situ. Then, the substrate 210 is aligned in successive steps by using the alignment mark 212 with enhanced step height, and more particularly in the steps of forming a color filter array 322. A color filter layer is formed on the dielectric layer 214 in the device region 216 by use of the alignment mark 212 with enhanced step height in an alignment process. Next, a color filer array 322 is formed on the dielectric layer 214 in the device region 216 by repeating the step of forming a color filter layer by use of the alignment mark 212 in the alignment process.

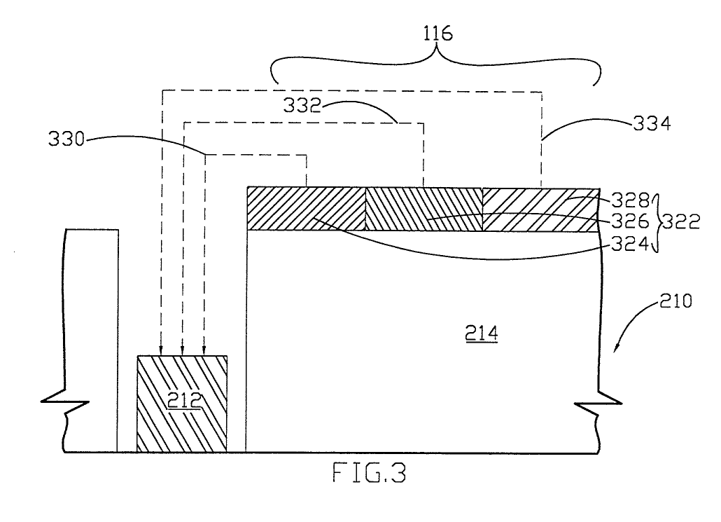

Referring to FIG. 3, the color filter array 322 comprises a set of primary color photoresist layers, such as red 324, green 326, and blue 328, photoresist layer is formed on the dielectric layer 214 in the device region 216. Three dot lines, 330, 332 and 334 represent the alignment processes of forming different color filter layers, respectively. The dot lines 330, 332 and 334 all show accurate alignments occurred due to the enhanced step height of the alignment mark 212, when each layer of the color filter array 322 is formed on the dielectric layer 214 in the device region 216, respectively. The alignment mark 212 with enhanced step height promotes the alignment precision in successive photolithography steps, even promotes the alignment precision in forming a color filter array by use of the color phtoresist with low permeability to the exposure light. That is to say, the alignment precision is improved by use of the alignment mark 212 with enhanced step height to increase the intensity of signal in semiconductor processes. The alignment precision by use of the present invention can be approached to ±0.2 μm.

The benefit achieved by this embodiment is that the alignment precision is improved with no extra step added in the flow of forming semiconductor devices. For example, in the flow of forming a color filter array, only the modification of patterning a desired shape on the photoresist is needed, wherein the photoresist is patterned with an opening overlying the alignment mark and a bonding opening in the device region in situ. As a result of the etching step, the alignment mark with enhanced step height is formed, and the desired bonding opening is formed in situ.

Although specific embodiments have been illustrated and described, it will be obvious to those skilled in the art that various modifications may be made without departing from what is intended to be limited solely by the appended claims.

What is claimed is:

1. A method for improving alignment precision in semiconductor processes, said method comprising:
providing a substrate having a node region in said substrate and a dielectric layer on said substrate; and
etching a portion of said dielectric layer to expose said node region,
whereby the alignment precision is improved by use of said node region with enhanced step height to increase the intensity of signal in semiconductor processes.

2. The method according to claim 1, wherein said substrate further comprises a device region.

3. The method according to claim 1, wherein said node region is an alignment mark.

4. The method according to claim 1, wherein said step of etching a portion of said dielectric layer to expose said node region comprises:
forming a patterned photoresist on said dielectric layer, wherein said patterned photoresist defines an opening overlying said node region;
etching a portion of said dielectric layer by using said patterned photoresist as a mask to expose said node region; and
removing said patterned photoresist.

5. The method according to claim 1, wherein said dielectric layer is a silicon oxynitride layer.

6. The method according to claim 2, wherein said method further comprises to form a color filter array on said dielectric layer in said device region.

7. The method according to claim 3, wherein said node region is an alignment mark used in a previous semiconductor step.

8. A method for improving alignment precision in semiconductor processes, said method comprising:
providing a substrate having an alignment mark in said substrate and a dielectric layer on said substrate;
forming a patterned photoresist on said dielectric layer, wherein said photoresist defines an opening overlying said alignment mark; and
etching a portion of said dielectric layer by using said patterned photoresist as a mask to expose said alignment mark,
whereby the alignment precision is improved by use of said alignment mark with enhanced step height to increase the intensity of signal in semiconductor processes.

9. The method according to claim 8, wherein said substrate further comprises a device region.

10. The method according to claim 8, wherein said dielectric layer is a silicon oxynitride layer.

11. The method according to claim 8, wherein said alignment mark is used in a previous alignment process.

12. The method according to claim 8, wherein said step of etching a portion of said dielectric layer further comprises removing said photoresist.

13. The method according to claim 9, wherein said method further comprises to form a color filter array on said dielectric layer in said device region.

14. A method for improving alignment precision in forming a color filter array, said method comprising:
providing a substrate having an alignment mark in said substrate and a dielectric layer on said substrate, wherein said substrate further comprises a device region;
forming a patterned photoresist on said dielectric layer, wherein said patterned photoresist defines an opening overlying said alignment mark;
etching a portion of said dielectric layer by using said patterned photoresist as a mask to expose said alignment mark;
removing said photoresist;
forming a color filter layer on said dielectric layer in said device region by using said alignment mark in an alignment process; and
repeating said step of forming said color filter layer to form said color filter array on said dielectric layer in said device region.

15. The method according to claim 14, wherein said alignment mark is a metal layer.

16. The method according to claim 14, wherein said dielectric layer is a silicon oxynitride layer.

17. The method according to claim 14, wherein said color filter array further comprises a set of primary color layers, wherein said color comprises red, green and blue.

18. The method according to claim 15, wherein said alignment mark is a metal layer alignment mark used in a previous alignment step.
